(19) United States
(12) Patent Application Publication
(10) Pub. No.: US 2001/0009284 A1
(43) Pub. Date: Jul. 26, 2001

(54) Bottom electrode of capacitor and fabricating method thereof

(76) Inventor: Sung-Han Yang, Cheongju (KR)

Correspondence Address: BIRCH, STEWART, KOLASCH & BIRCH, LLP, P.O. Box 747, Falls Church, VA, 22040-0747, US

(21) Appl. No.: 09/745,533

(22) Filed: Dec. 26, 2000

(30) Foreign Application Priority Data
Jan. 25, 2000 (KR) 3417/2000

(51) Int. Cl. H01L 21/8242; H01L 27/108; H01L 29/76; H01L 29/94; H01L 31/119; H01L 21/20

(52) U.S. Cl. 257/306; 257/296; 257/303; 257/308; 257/309; 361/303; 438/244; 438/253; 438/387; 438/396; 438/399; 438/255; 438/398; 438/665

(57) ABSTRACT

A bottom electrode of a capacitor and a method of fabrication is described. Hemispherical grained silicon (HSG) flexures are formed on a storage node to increase the effective area of the capacitor to increase the capacitance. The storage node includes a first region doped with phosphorous and a second undoped region. HSG flexures are formed on the surfaces of both the first and second region. Flexures formed on the first region are smaller in size than the flexures formed on the second region. This prevents adjacent storage nodes from becoming short-circuited with each other. Also, concave portions are formed on the second region between adjacent flexures. This further increases the effective surface area of the capacitor, which further increases the capacitance of the capacitor.

### BACKGROUND OF THE INVENTION

The present invention relates to a semiconductor device, and more particularly, to a bottom electrode of a capacitor and its fabricating method, which is capable of preventing a short between storage nodes, with an increase of an effective surface area.

A memory cell of a DRAM (dynamic random access memory) includes two major parts, a field effect transistor and a capacitor. As the level of integration of a memory device is increased, the area occupied by the capacitor in each cell is reduced, causing various problems as described below.

First, a soft error occurs. The soft error is due to alpha particles, generated when radioactive impurities decay within an IC package, are incident on the memory chip. This generates electron-hole pairs, which accumulate on a depletion region of a p-n junction.

Since information is stored as bits in a memory device such as a DRAM or an SRAM according to whether or not charges are accumulated in a potential well of the capacitor, the generation of the electron-hole pairs disturbs the charge state of the capacitor. This in turn disturbs the information stored in the memory device.

Second, the capacitance of each cell is reduced due to the reduction in the area of the capacitor. This necessitates an increase in refresh frequency. Thus the operation of the device is frequently stopped for refreshing.

To cope with the problem of the reduction of the area of the memory cell, particularly the area of the capacitor, various methods are being studied so that a sufficient capacitance may be maintained for each capacitor. The studies are mostly either material or structural.

In materials research, studies typically focus on replacing the existing silicon oxide dielectric film with a dielectric film having a high dielectric constant such as tantalum oxide film (Ta₂O₅) or BST ((Ba, Sr) TiO₃). In structural research, studies typically focus on either thinning the dielectric film or on increasing effective surface area.

However, the materials and the dielectric thinning methods are limited. The materials method, i.e. incorporating dielectric films with high dielectric constants, is limited because the existing process needs to be significantly or even wholly modified. The dielectric thinning is limited because a thin dielectric has disadvantageous leakage characteristics. Thus, recent research has focused on maintaining sufficient capacitance by increasing the effective surface area.

Two types of capacitors have been used to increase the effective surface area—a trench capacitor and a stacked capacitor. The trench capacitor is formed by first forming a trench on a semiconductor substrate and then forming a capacitor in the trench. A stacked capacitor is where multiple capacitors are stacked to increase the effective surface area.

Recently, a method for enlarging the effective surface area using a HSG (hemispherical grained silicon) has been researched. In this method, the stacked capacitor is modified.

There are at least two ways to form HSG on a capacitor. First, silicon particles are deposited by the chemical vapor deposition method at a constant temperature and pressure. This generates anomalous nucleation, and thereby forms flexures on the surface.

Second, as shown in FIG. 1, after an amorphous silicon film 3 is deposited on a crystalline silicon film 1, Si₂H₆ or SiH₄ gas is decomposed at a temperature of 500° C.˜600° C. and at a pressure of 10⁻⁷˜10⁻⁸ torr in a vacuum annealing chamber, so that the silicon particles can serve as nucleation sites. A thermal treatment moves the silicon particles to the form convex flexures 5.

Though both methods obtain a much larger effective surface area due to the flexures formed on the surface compared to a flat surface, since the method using the vacuum annealing is simpler, it is more popular, and will now be explained.

FIG. 2 illustrates a semiconductor device including bottom electrodes using the HSG in accordance with the conventional art.

As shown, field oxide layers 12 are formed on the upper surface of the semiconductor substrate 10 at predetermined intervals. On the upper surface of the semiconductor substrate including the field oxide layers 12, dielectric layers 14 are formed with contact openings 18 at predetermined intervals.

The contact openings 18 expose impurity regions (not shown) formed on predetermined regions of the semiconductor substrate. Storage nodes 20, made of the crystalline silicon, are formed on the dielectric layers 14. The storage nodes 20 are electrically connected to the impurity regions of the semiconductor substrate 10 through the contact holes 18. An amorphous silicon layer 21 is formed on the upper and side surface of the storage node 20, and HSG flexures 25 are formed on the upper surface of the amorphous silicon layer 21.

When the HSG flexures 25 are formed on the upper surface of the amorphous silicon layer 21, the size of the HSG flexures 25, in a region 27 between the storage nodes 20, need to be adjusted to prevent an electrical short between the storage nodes. If the HSG flexures 25 in the region 27 are excessively large, the HSG flexures 25 of each storage node 20 would contact each other causing a short circuit between the storage nodes 20.

In the conventional art, physical parameters are adjusted to control the size of the HSG. These parameters include lowering the amount of flow of gases Si₂H₆ and SiH₄, lowering the temperature for the thermal treatment, or even reducing the amount of time for the thermal treatment.

However, this reduces the size of the HSG flexures formed in regions other than the region 27 between the storage nodes. Unfortunately, this reduces the increase in effective surface area of the capacitor. As a result, the benefits, such as increase in capacitance and reduction in refresh frequency, are also reduced.

### SUMMARY OF THE INVENTION

Therefore, an object of the present invention is to provide a bottom electrode of a capacitor and a fabricating method to increase the effective surface area of a capacitor while preventing shorts between adjacent storage nodes.

To increase the effective surface area, an embodiment of the present invention grows HSG flexures on the surfaces of the storage node. The surface area is further increased by forming concave portions on the storage node.

To prevent shorts, HSG flexures grown on surfaces of the storage node adjacent to another storage node is smaller in size relative to HSG flexures grown on other surfaces of the storage node.

To achieve these and other advantages and in accordance with the purposed of the present invention, as embodied and broadly described herein, a bottom electrode of a capacitor according to an embodiment of the present invention includes: a semiconductor substrate including an impurity region; a storage node electrically connected to the impurity regions of the semiconductor substrate, the storage node being divided into a doped first region and an undoped second region; and flexures formed on the second region of the storage node.

A method to form the bottom electrode of a capacitor according to the embodiment of the present invention includes: forming an impurity region on a predetermined portion of a semiconductor substrate; forming a dielectric layer on an upper surface of the semiconductor substrate with a contact opening formed therein exposing the impurity region; forming a storage node on the upper surface of the dielectric layer, the storage node being electrically connected to the impurity region through the contact opening, and the storage node being divided into first and second regions; and forming flexures on surfaces of the first and second regions.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a cross-sectional view of a bottom electrode of a capacitor using a HGS in accordance with a conventional art;

FIG. 2 is a cross-sectional view of a semiconductor device including the capacitor bottom electrode using the HGS in accordance with the conventional art;

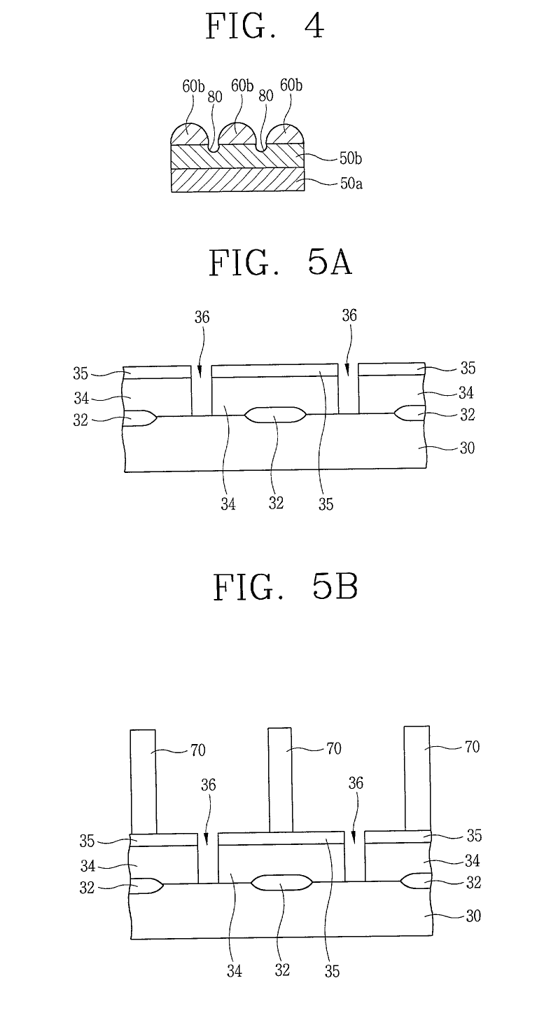

FIG. 3 a cross-sectional view of a semiconductor device including a bottom electrode of a capacitor using the HGS in accordance with an embodiment of the present invention;

FIG. 4 is a cross-sectional view enlarging ‘A’ portion of FIG. 3 in accordance with the embodiment of the present invention;

FIGS. 5A through 5G show a sequential process of a method for fabricating the bottom electrode of a capacitor using the HSG in accordance with the embodiment of the present invention.

### DETAILED DESCRIPTION OF THE PREFERRED EMBODIMENTS

Reference will now be made in detail to the preferred embodiment of the present invention, examples of which are illustrated in the accompanying drawings.

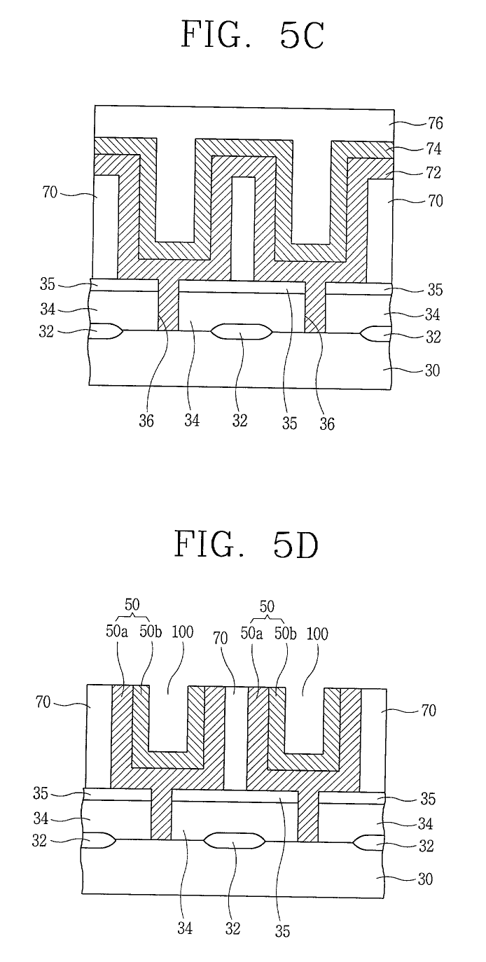

FIG. 3 shows a cross-sectional view of a semiconductor device including a bottom electrode of a capacitor using the HGS in accordance with the embodiment of the present invention.

As shown, field oxide layers 32 are formed at predetermined intervals on the upper surface of a semiconductor substrate. First dielectric layers 34 are formed on the semiconductor substrate including field oxide layers 32 together with contact openings 36 formed at predetermined intervals thereon. The contact openings 36 expose impurity regions (not shown) formed on predetermined regions of the semiconductor substrates.

Second dielectric layers 35 are formed on the surface of the first dielectric layers. The first dielectric layer 34 is typically made of an oxide, while the second dielectric layer 35 is typically made of a nitride.

Storage nodes 50 are formed on the upper surface of the second dielectric layers 35. The storage nodes 50 are electrically connected to the impurity regions (not shown) through the contact openings 36. Each storage node 50 includes a first region 50a doped with phosphorous and an undoped second region 50b. The storage node 50 is made of silicon. In the present embodiment, the storage node 50 is preferably made of an amorphous silicon.

Hemispherical grained silicon (HSG) flexures 60 are formed on the upper and side surface of the storage nodes 50. Flexures 60a, formed on the first region 50a, are small in size. This prevents the possibility of the storage nodes 50 from being short-circuited with each other. Also, flexures 60b, formed on the second region 50b, are relatively large. Thus, the second region retains a large effective surface area.

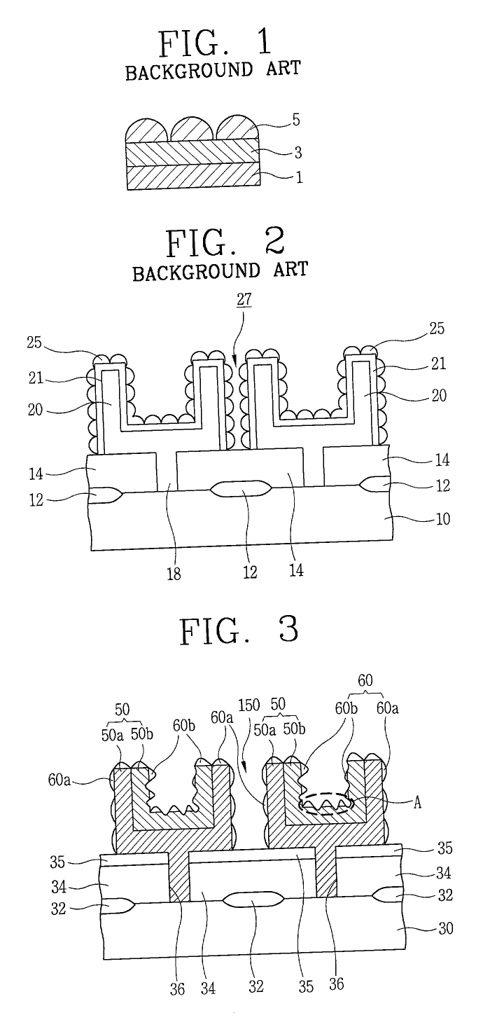

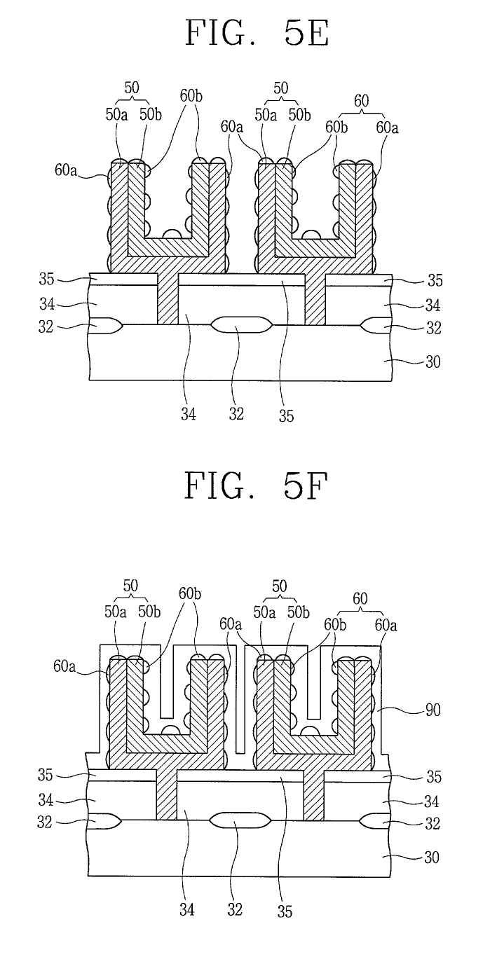

FIG. 4 is a cross-sectional view enlarging ‘A’ portion of FIG. 3. As shown, the second region 50b, between the individual flexures 60b, is etched to form concave portions 80. The result is that the effective surface area is further increased when compared to the conventional art of FIG. 1.

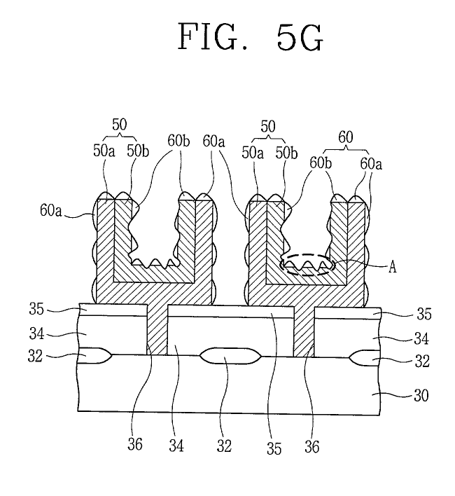

FIGS. 5A through 5G show a method for fabricating the bottom electrode of a capacitor using the HSG in accordance with the embodiment of the present invention.

First, as shown in FIG. 5A, field oxide layers 32 are formed at predetermined intervals on the semiconductor substrate 30.

Subsequently, the first dielectric layer 34, made of an oxide, and the second dielectric layer 35 are sequentially formed on the upper surface of the semiconductor substrate 30 including the field oxide layers 32.

Then, the second dielectric layer 35 and the first dielectric layer 34 are partially etched sequentially, to form the contact openings 36 at predetermined intervals.

As shown in FIG. 5B, third dielectric layers 70, typically made of a plasma enhanced TEOS (PE-TEOS), are thickly formed on the upper surface of the second dielectric layers 35 and patterned so that the contact openings 36 and predetermined portions of the second dielectric layer 35 are exposed.

Next, as shown in FIG. 5C, a doped silicon layer 72 is formed on the upper and side surface of the third dielectric layer 70, on the upper surface of the second dielectric layer 35 and in the contact opening 36. And then an undoped silicon layer 74 is formed on the upper and side surface of the doped silicon layer 72. It is preferable that both the doped silicon layer 72 and the undoped silicon layer 74 are made of amorphous silicon.

And then, a fourth dielectric layer 76, typically made of an SOG (spin on glass), is formed on the upper surface of the undoped silicon layer 74.

Thereafter, as shown in FIG. 5D, the fourth dielectric layer 76, the undoped silicon layer 74, and the doped silicon layer 72 are abraded by the chemical-mechanical polishing process or etched to expose an upper surface of the third dielectric layer 70. At this point, the storage nodes 50, including the first region 50a made of the undoped silicon layer 74 and the second region 50b made of the doped silicon layer 72, are formed.

Subsequently, the remaining fourth dielectric layer 76 in regions 100, within the second regions 50b of each storage node 50, is removed by etching.

Next, as shown in FIG. 5E, the third dielectric layer 70 remaining on the semiconductor substrate is also removed by etching. Then Si₂H₆ or SiH₄ gas is decomposed at the temperature of 500˜600° C. and at the pressure of 10⁻⁷˜10⁻⁸ torr in a vacuum annealing chamber to deposit silicon particles (not shown). The deposited silicon particles serve as a nucleation site on the upper surfaces of the storage node 50.

Thereafter, when a thermal treatment is performed, the silicon particles, forming the storage nodes 50, move to form the HSG flexures 60.

The flexures 60 are more actively generated on the portions of the storage nodes 50 where there is relatively less concentration of phosphorous doping. As a result, the flexures 60b formed on the second region 50b (undoped silicon) are larger than the flexures 60a formed on the first region 50a (silicon doped with phosphorous) of the storage node 50. Also, the phosphorous concentration of flexures 60b is lower than the phosphorous concentration of areas between the HSG flexures 60b on the second region 50b.

The above-described method forms the HSG by anomalous nucleation and thermal treatment. However, a method in which the silicon particles are deposited by chemical vapor deposition at a constant temperature and pressure to generate anomalous nucleation, can be also adopted.

Next, as shown in FIG. 5F, an oxide film 90 is formed having a thickness of 50˜70 Å on the upper surface of the storage node 50 including the HSG 60. The oxide film 90 is formed by deposition or a thermal oxidation.

When forming the oxide film 90, the phosphorous doping serves to increase the growth speed of the oxide film 90. As mentioned above, on the second region 50b, the areas between the flexures 60b have relatively higher concentration of phosphorous than the flexures 60b. Accordingly, when the oxide grows, the silicon undergoing transmutation is greater in the areas between the flexures 60b than the flexures 60b themselves.

Finally, the oxide film 90 is removed by etching, which completes the fabrication of the bottom electrode of the capacitor. A wet etching is preferred to etch the oxide film 90.

The phosphorous serves to increase the etching speed when the oxide film is etched. Accordingly, etching speed is faster in the area on the second region between the HSG flexures 60b than in the flexures 60b.

Also as mentioned above, the amount of the silicon undergoing transmutation, when the oxide film is formed, is greater in areas between the flexures 60b. Thus, after the oxide is etched, the areas between the flexures 60b of the second region 50b are etched to form the concave portion 80, as shown in FIG. 4.

As described, according to the bottom electrode of the capacitor and its fabricating method of the embodiment of the present invention, the growth of the flexures between the storage nodes is restrained. This limits or prevents the possibility that an electrical short will occur between the storage nodes.

In addition, the concave portions are formed on the surface of the storage node in areas between the flexures. This enlarges the effective surface area of the bottom electrode, so that the capacitance of the capacitor can be increased.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A bottom electrode of a capacitor, comprising:
a semiconductor substrate including an impurity region;
a storage node electrically connected to the impurity regions of the semiconductor substrate, the storage node being divided into a doped first region and an undoped second region; and
at least one flexure formed on the second region of the storage node.

2. The bottom electrode of a capacitor according to claim 1, wherein the storage node is made of silicon.

3. The bottom electrode of a capacitor according to claim 1, wherein the silicon is made of amorphous silicon.

4. The bottom electrode of a capacitor according to claim 1, wherein the HSG is generated on the surfaces of the first and the second regions.

5. The bottom electrode of a capacitor according to claim 1, wherein the first region is a doped with phosphorous.

6. The bottom electrode of a capacitor according to claim 5, wherein at least one flexure is formed on the first region.

7. The bottom electrode of a capacitor according to claim 6, wherein the flexure formed on the first region is smaller than the flexure formed on the second region.

8. The bottom electrode of a capacitor according to claim 1, wherein at least one concave portion is formed on the second region in areas between the flexures.

9. A method for fabricating a bottom electrode of a capacitor, the method comprising:
forming an impurity region on a predetermined portion of a semiconductor substrate;
forming a dielectric layer on an upper surface of the semiconductor substrate with a contact opening formed therein exposing the impurity region;
forming a storage node on the upper surface of the dielectric layer, the storage node being electrically connected to the impurity region through the contact opening, and the storage node being divided into first and second regions; and
forming at least one flexure on surfaces of each of the first and second regions.

10. The method according to claim 9, wherein the flexure formed on the first region is smaller than the flexure formed on the second region.

11. The method according to claim 9, wherein the first region is made of a doped amorphous silicon and the second region is made of an undoped amorphous silicon.

12. The method according to claim 9, further comprising:
forming an oxide film on the upper surface of the flexure; and
etching the oxide film.

13. The method according to claim 12, wherein the oxide film is formed by one of deposition and thermal oxidation.

14. The method according to claim 12, wherein the etching of the oxide film is performed by a wet-etching method.

15. The method according to claim 12, wherein the oxide film is formed having the thickness of 50˜80 Å.

16. The method according to claim 9, wherein the dielectric layer is formed by sequentially stacking a first dielectric layer made of an oxide and a second dielectric layer made of a nitride.

17. The method according to claim 16, wherein the sub-method of forming the storage node comprises:
depositing a third dielectric layer on the second dielectric layer and patterning it to expose the contact opening;
forming a doped amorphous silicon layer to cover the third dielectric layer and the contact opening;
forming an undoped amorphous silicon layer to cover the doped amorphous silicon layer;
forming a fourth dielectric layer to cover the undoped amorphous silicon layer;
exposing an upper surface of the third dielectric layer by removing portions of the fourth dielectric layer, the undoped amorphous silicon layer, and the doped amorphous silicon layer; and
removing the fourth and the third dielectric layers.

18. The method according to claim 9, wherein the sub-method of forming the flexure comprises:
depositing silicon, serving as a nucleation site, on the upper surface of the storage node; and
moving the silicon constructing the storage nodes to nucleation sites through a thermal treatment.

19. The method according to claim 18, wherein the silicon is deposited at a temperature ranging between 500˜600° C. and at a pressure ranging between 10⁷˜10⁻⁸ torr.

20. The method according to claim 18, wherein the silicon is deposited by decomposing Si₂H₆ or SiH₄ gas.

21. The bottom electrode of a capacitor according to claim 1, wherein the flexure is formed of hemispherical grained silicon (HSG).

22. The method according to claim 9, wherein the flexures are formed using HSG.

23. A method to form a bottom electrode of a capacitor, the method comprising:
forming a semiconductor substrate including at least one impurity region defined therein; and
forming a storage node electrically connected to said impurity region, said storage including a first surface facing a surface of another storage node and a second surface not facing said surface of said another storage node, said first surface including at least one flexure and said second surface including at least one flexure, wherein said flexure of said first surface is smaller than said flexure of said second surface.

24. The method of claim 23, further comprising:
forming at least one concave portion on said second surface on an area not occupied by said flexure of said second surface.

25. The method of claim 24, wherein said storage node is made of a first region and a second region such that a surface of said first region is said first surface and a surface of said second region is said second region.

26. The method of claim 25, wherein said first region is doped and said second region is not doped.

27. The method of claim 26, wherein said first region is doped with phosphorous.

28. A bottom electrode of a capacitor, comprising:
a semiconductor substrate including an impurity region;
a storage node electrically connected to said impurity regions of the semiconductor substrate;
a first flexure formed on said storage node; and
at least one of a concave portion and a second flexure of different size formed on said storage node.

29. A method to form a bottom electrode of a capacitor, the method comprising:
forming a semiconductor substrate including an impurity region;
forming a storage node electrically connected to said impurity regions of the semiconductor substrate;
forming a first flexure on said storage node; and
forming at least one of a concave portion and a second flexure of different size on said storage node.
